(19) United States
(12) Patent Application Publication
(10) Pub. No.: US 2007/0136018 A1
(43) Pub. Date: Jun. 14, 2007

(54) Nonlinear model calibration using attenuated stimuli

(76) Inventors: Andrew D. Fernandez, Palo Alto, CA (US); Robert C. Taber, Palo Alto, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/299,001

(22) Filed: Dec. 9, 2005

(51) Int. Cl. G01R 35/00

(52) U.S. Cl. 702/86

(57) ABSTRACT

A system and method are disclosed for calibrating non-linear behavior using attenuated stimuli and responses which allows for calibration with unknown stimulus and less expensive sources and receivers. The device under test is stimulated with a signal and then an attenuated version of the same signal, so that non-linear differences between responses can be attributed to the device rather than the signal source. Alternatively, or in conjunction with attenuation of the stimulus, the output of the device at different response amplitudes can be selectively attenuated such that the receiver measures approximately the same amplitude. This allows non-linear differences between measurements to be attributed to the device rather than the receiver. Two or more different signal sources can also be used, where responses are measured for each signal individually and then for at least one linear combination of signals.

### FIELD OF THE INVENTION

The present invention is directed generally to calibrating systems for linear behavior, and more particularly to characterizing nonlinear behavior of systems using non-ideal test equipment.

### DESCRIPTION OF RELATED ART

All analog electronic devices have some component of nonlinear behavior. A system's accuracy is often limited by the nonlinearities of its constituent components. For example, signal generators and signal analyzers today are limited in dynamic range due to the nonlinear behavior of their analog and mixed signal components. Digital signal processing is sometimes used to linearize such a system.

Several techniques for linearizing a system exhibiting nonlinear behavior involve building a mathematical model for that nonlinear behavior. If the system exhibits a “weak” nonlinearity, it is possible to use the nonlinear model and the output or input of the system to predict the nonlinear behavior of the system. With an appropriate model, one may either pre-distort or post-distort the data and linearize the system. It is common to characterize a nonlinear model for a particular system, and then apply it to several related systems. In this case, the model structure does not change between applications. However, the coefficients of that model may require re-adjustment. This calibration process fits a generic model structure to a specific system.

The process of calibration is typically time consuming and requires specialized equipment. The typical calibration approach applies a stimulus signal to the nonlinear device and then measures the device's response. The nonlinear component of the difference between the stimulus and response provides the necessary information to calibrate the nonlinear model. An underlying assumption to this approach is that the stimulus and response are known. For many situations, this is not an unreasonable assumption. Typical methods of calibration also rely on a signal source or receiver that is significantly more linear than the system to be calibrated. Unfortunately, if the device under test is extremely linear, it is often difficult or impossible to find test equipment to either generate or capture waveforms without introducing errors comparable to the nonlinear behavior of the device under test (DUT). Even if such test instruments are available, they are often prohibitively expensive to build into the system to be linearized for the sole purpose of calibration.

### BRIEF SUMMARY OF THE INVENTION

Representative embodiments of the present invention provide for a method of calibrating a nonlinear model with an imperfect (nonlinear) signal source or an imperfect (nonlinear) signal receiver, or both an imperfect (nonlinear) signal source and an imperfect (nonlinear) signal receiver simultaneously. Representative embodiments of the invention also provide for a blind approach to nonlinear equalization, an approach which can use a stimulus signal that is unknown. These features are in contrast to typical calibration approaches described previously, which require a priori knowledge of the calibration signal, a highly linear signal source and a highly linear signal receiver.

Representative embodiments of the present invention will compare a response to an original stimulus with a response to an attenuated stimulus. Generally, an attenuated stimulus will generate lower levels of nonlinear behavior in a DUT relative to the original stimulus. Since an attenuator will be highly linear, nonlinear differences can be attributed to the DUT. Attenuation may be used for both input and output signals, such that nonlinearities in a signal source and a signal receiver do not introduce nonlinearities in the measurements. That is, a signal source may generate identical signals for two or more stimulus levels, but the difference in stimulus levels will be due to linear attenuators, rather than changes in the signal source output. Thus, signal source behavior will be reproduced exactly, and nonlinearities in the signal source will not appear in measurement results. Similarly, signals output from a DUT may be attenuated by various levels of attenuation, such that the signals appearing at a signal receiver are approximately the same magnitude. Thus, the signal receiver may be assumed to be linear over the range of received signals. Any observed nonlinear behavior, therefore, can be attributed to the DUT.

Representative embodiments of the present invention will compare responses to multiple stimuli both individually and in linear combination, where each signal source produces a consistent signal for measurements of both individual and combination responses. That is, a first signal source may generate a first signal, and the response is measured. Then a second source may generate a second signal, and that response is measured. Finally, with the first signal source generating the same first signal, and the second source generating the same second signal, the first and second signals may be combined linearly to produce a third signal. The response of the third signal may be measured, and any nonlinearities in the response can be attributed to nonlinearities in the device. Representative embodiments using linear combinations of stimuli may also use attenuation of the device output as described above, in order to minimize the effect of nonlinearities in the receiver.

Representative embodiments of the present invention enable calibration without specialized equipment and are applicable with arbitrary waveforms. Since scaling and additive properties of linear systems are not obeyed in nonlinear systems, linearly scaling or adding signals outside a device to be calibrated highlights the difference between linear and nonlinear system behavior. Such differences may be used to build and calibrate nonlinear models of the behavior. While sources and receivers may not replicate or measure a known signal perfectly, their behavior for an arbitrary signal is often suitably repeatable. This repeatability can be used to coherently average signals, which recovers dynamic range that may be lost by attenuation.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 shows a prior art calibration configuration;

FIG. 2 shows an embodiment of a calibration configuration for use with a non-ideal source;

FIG. 3 illustrates an embodiment of a calibration method for use with a non-ideal source;

FIG. 4 shows an embodiment of a calibration configuration for use with a non-ideal receiver;

FIG. 5 illustrates an embodiment of a calibration method for use with a non-ideal receiver;

FIG. 6 shows an embodiment of a calibration configuration for use with a non-ideal source and a non-ideal receiver;

FIG. 7 illustrates an embodiment of a general calibration method from which other specific embodiments can be derived;

FIG. 8 shows an embodiment of a calibration configuration for use with multiple non-ideal sources;

FIG. 9 illustrates an embodiment of a calibration method for use with multiple non-ideal sources.

FIG. 10 shows an embodiment of a calibration configuration wherein either a source or a receiver is to be calibrated;

FIG. 11 shows an embodiment of a calibration configuration wherein a nonlinear source is to be calibrated using a non-ideal receiver; and

FIG. 12 shows an embodiment of a calibration configuration wherein a nonlinear receiver is to be calibrated using a non-ideal source.

### DETAILED DESCRIPTION OF THE INVENTION

It will be understood that the inventive concepts described herein may be adapted for use to calibrate nonlinear models using attenuation or linear combinations of stimuli and/or attenuation of responses from a device under test (DUT). What follows will be understood to be specific embodiments, and the present invention need not be limited to only the embodiments described.

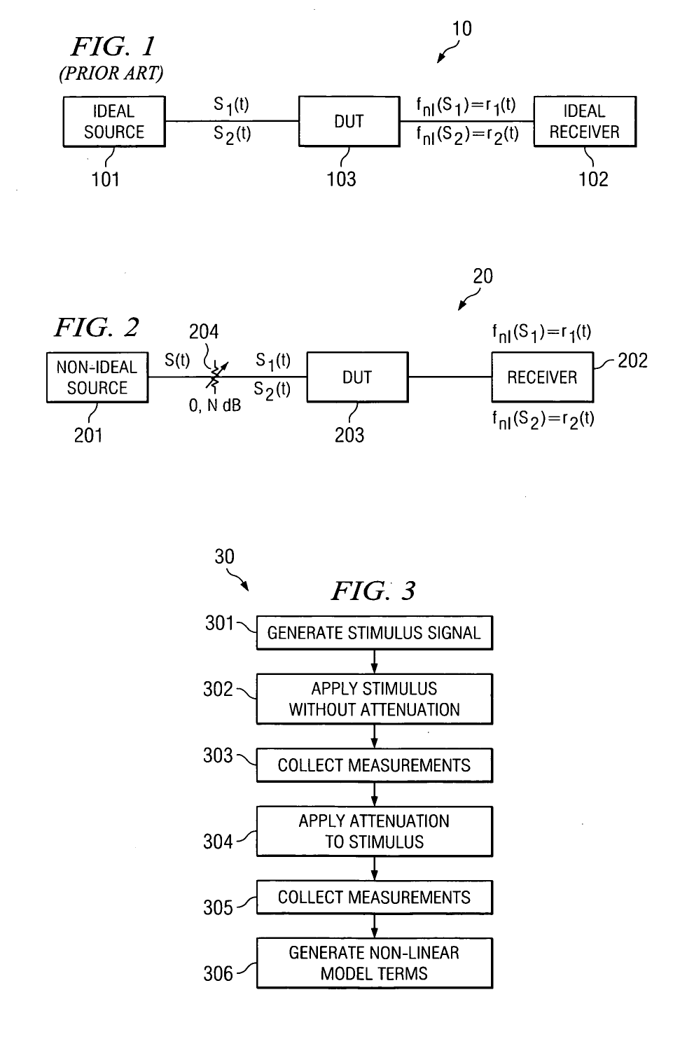

FIG. 1 shows prior art calibration configuration 10. Ideal source 101 stimulates DUT 103, and ideal receiver 102 collects measurements. First, ideal source 101 generates stimulus s₁(t) and DUT 103 outputs response r₁(t). Next, ideal source 101 generates stimulus s₂(t) and DUT 103 outputs response r₂ (t). Although ideal source 101 and ideal receiver 102 may not be truly ideal, they are highly linear compared to DUT 103, so that any nonlinearities in the measurements of responses r₁(t) and r₂(t) are attributable to DUT 103. However, if DUT 103 is extremely linear, it may be difficult or impractical to obtain ideal source 101 and ideal receiver 102 that have suitable performance.

FIG. 2 shows an embodiment of a calibration configuration according to the concepts described herein. Calibration configuration 20 illustrates a calibration configuration for use with non-ideal source 201. Non-ideal source 201 is considered non-ideal because it is not expected to produce two different stimulus signals with highly linear performance when compared with the performance of DUT 203. Therefore, non-ideal source 201 it is set to generate only a single stimulus s(t). Attenuator 204 is placed in the signal path between non-ideal source 201 and receiver 202. In the embodiment shown in FIG. 2, attenuator 204 is placed between non-ideal source 201 and DUT 203. Attenuator 204 can either be switchable between 0 dB (no attenuation) and N dB, or else it could be removed for the 0 dB attenuation and set in place for N dB attenuation. When the attenuation is set to a value of 0, i.e. there is no attenuation, generated stimulus s(t) becomes applied stimulus s₁(t), which is applied to DUT 203. DUT 203 outputs response r₁(t) to receiver 202. When the attenuation is set to a value of N dB, generated stimulus s(t) becomes applied stimulus s₂(t), which is applied to DUT 203. DUT 203 outputs response r₂(t) to receiver 202. Since attenuator 204 can be assumed to be linear, any nonlinearities in responses r₁(t) and r₂(t) can be attributed to DUT 203, rather than non-ideal source 201.

Attenuator 204 may have frequency-dependent behavior, which may drive the requirement for multiple attenuators, each providing the function of attenuator 204 for specific frequency bands. Additionally, although calibration configuration 20 is described above as having two levels of attenuation, 0 and N dB, it could use multiple levels of attenuation or two levels of attenuation, N₁ dB and N₂ dB, where neither level is 0.

FIG. 3 shows method 30 illustrating an embodiment of a calibration method according to the concepts described herein. Reference is made to calibration configuration 20 of FIG. 2 to illustrate method 30. Stimulus signal s(t) is generated during process 301 and applied to DUT 203 without attenuation 302. Receiver 202 collects measurements during process 303. With source 201 generating the same stimulus signal s(t), attenuation is applied 304 to produce s₂(t). Another set of measurements is collected 305, allowing for the generation of non-linear model terms during process 306. Measurements may be coherently averaged in order to reduce the noise floor.

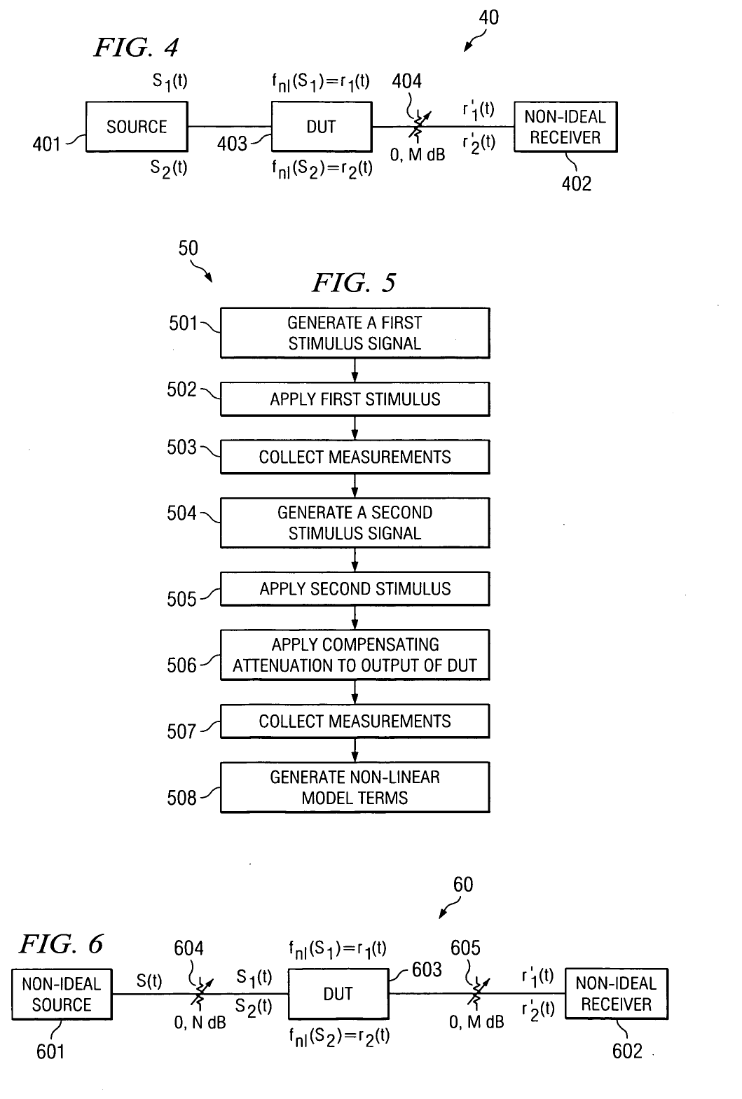

FIG. 4 shows an embodiment of a calibration configuration according to the concepts described herein. Calibration configuration 40 illustrates a calibration configuration for use with non-ideal receiver 402. Non-ideal receiver 402 is considered non-ideal because it is not expected to measure two different stimulus signals with highly linear performance when compared with the performance of DUT 403. Source 401 generates two stimulus waveforms, s₁(t) and s₂(t), which differ by a scale factor. When DUT 403 is stimulated by s₁(t), it produces response r₁(t). Attenuator 404 is switched to an attenuation value of 0 dB to send measured response r′₁(t) to non-ideal receiver 402. Attenuator 404 may need to be removed or bypassed to provide an attenuation value of 0. When DUT 403 is stimulated by s₂(t), it produces response r₂(t). Attenuator 404 is set to an attenuation value of M dB to attenuate r₂(t) to measured response r′₂(t), where M is chosen such that r′₂(t) has approximately the same amplitude as r′₁(t). In this way, non-ideal receiver 402 may be assumed to be linear over the range of amplitudes from that of r′₁(t) through that of r′₂(t). Thus, any nonlinearities in the measured, attenuated responses r′₁(t) and r′₂(t) can be attributed to DUT 403, rather than non-ideal receiver 402.

Attenuator 404 may have frequency-dependent behavior, which may drive the requirement for multiple attenuators, each providing the function of attenuator 404 for specific frequency bands. Although calibration configuration 40 is described above as having two levels of attenuation, 0 and M dB, it could use multiple levels of attenuation or two levels of attenuation, M₁ dB and M₂ dB, where neither level is 0. Additionally, the description above gives an attenuation value of 0 when s₁(t) is applied and M dB when s₂(t) is applied. There is no requirement to use a lower attenuation value first, nor is the M dB value shown in FIG. 4 necessarily the same value as N dB shown in FIG. 2. The terms N dB and M dB describe appropriate non-zero attenuation values.

FIG. 5 shows method 50 illustrating an embodiment of a calibration method according to the concepts described herein. Reference is made to calibration configuration 40 of FIG. 4 to illustrate method 50. A first stimulus signal, s₁(t), is generated during process 501 and applied to DUT 403 during process 502. Receiver 402 collects measurements during process 503. A second stimulus signal, s₂(t), is produced during process 504 and applied to DUT 403 during process 505. Process 504 could include generation of s₁(t) along with attenuation in order to produce s₂(t). Compensating attenuation is applied to the output of DUT 403 in process 506, such that a response measured in process 507 has approximately the same amplitude as a measured response in process 503. Measurements may be coherently averaged in order to reduce the noise floor. Nonlinear model terms are generated during process 508.

FIG. 6 shows an embodiment of a calibration configuration according to the concepts described herein. Calibration configuration 60 illustrates a calibration configuration for use with non-ideal source 60 and non-ideal receiver 602. Non-ideal source 601 and non-ideal receiver 602 are considered non-ideal because neither is expected to operate with highly linear performance when compared with the performance of DUT 603. Since non-ideal source 601 is not expected to produce two different stimulus signals linearly, it is set to generate only stimulus s(t). Attenuator 604 is placed between non-ideal source 601 and DUT 603. Attenuator 604 could either be switchable between 0 dB (no attenuation) and N dB, or else it could be removed for the 0 dB attenuation and set in place for N dB attenuation. When the attenuation is set to a value of 0, i.e. there is no attenuation, generated stimulus s(t) becomes applied stimulus s₁(t), which is applied to DUT 603. DUT 603 outputs response r₁(t). Attenuator 605 is switched to an appropriate attenuation value, either 0 dB or M dB, to attenuate response r₁(t) to measured response r′₁(t), which is measured by non-ideal receiver 602. The attenuation value is chosen such that r′₁(t) is approximately the same amplitude as measured response r′₂(t), discussed below. Attenuator 605 may need to be removed or bypassed to provide an attenuation value of 0.

With non-ideal source 601 generating s(t), attenuator 604 is set to a value of N dB. Generated stimulus s(t) becomes applied stimulus s₂(t), which is applied to DUT 603. DUT 603 outputs response r₂(t). Attenuator 605 is switched to an appropriate attenuation value, either 0 dB or M dB, to attenuate response r₂(t) to measured response r′₂(t), which is measured by non-ideal receiver 602. The attenuation value is chosen such that r′₂(t) is approximately the same amplitude as r′₁(t). In this way, any nonlinearities in the measured, attenuated responses r′₁(t) and r′₂(t) can be attributed to DUT 603, rather than non-ideal source 601 or non-ideal receiver 602.

It should be noted that in certain embodiments of the invention, multiple attenuation values may be used, in excess of two. These multiple attenuation values may or may not include an attenuation value of 0 dB. Additionally, multiple generated stimulus signals may be used in order to characterize nonlinearities in DUT 603, including signals in multiple frequency bands. Attenuator 604 may have frequency-dependent behavior, which may drive the requirement for multiple attenuators, each providing the function of attenuator 604 for specific frequency bands.

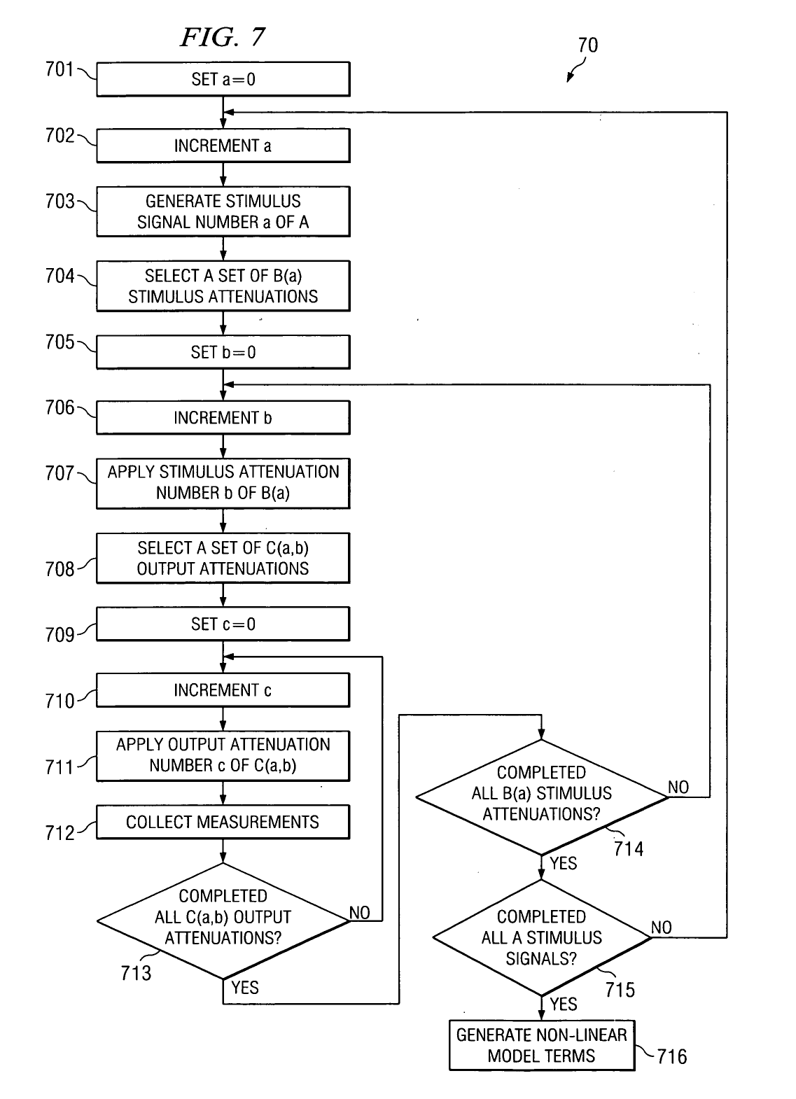

FIG. 7 shows method 70 illustrating an embodiment of a calibration method according to the concepts described herein. Method 70 demonstrates that multiple stimulus signals can be used. For each stimulus signal, there is a set of attenuations, possibly including an attenuation value of 0. For each stimulus attenuation, there is a set of response attenuations, also possibly including an attenuation value of 0. In 701, the index a, for counting the set of generated stimulus signals, is set to 0. In 702, index a is incremented. The first iteration of 702 sets a to 1. This may or may not be the only value used for a. During process 703, stimulus signal #a of A is generated, where A represents the total number of different stimulus signals to be generated. A set of B stimulus attenuations is selected, based on the current stimulus signal, in process 704. In 705, index b is reset to 0, and then incremented 706. The reason for the reset and increment of b is to allow for nested iterations of applying attenuation, in the event that multiple stimulus signals are generated by a return to 702 and 703.

The stimulus attenuation is selected and applied during process 707, possibly including an attenuation value of 0. A set of C response attenuations is selected during process 708, based on the current stimulus signal and the current stimulus attenuation. The set of C response attenuations may include compensating values, such that multiple DUT response levels can be brought into similar amplitude levels for measurement. In 709, c is set to 0, and then incremented 710. In process 711, response attenuation #c of C is applied, and a receiver collects a set of measurements 712 . In decision 713, if another response attenuation is desired for the current stimulus signal and stimulus attenuation, the procedure is returned to 710, incrementing c. In decision 714, if another stimulus attenuation is desired for the current stimulus signal, the procedure is returned to 706, incrementing b. . In decision 715, if another stimulus is desired, the procedure is returned to 702, incrementing a. A new stimulus signal could be a signal from a different generator, or a combination of signals from multiple generators. During process 716, nonlinear model terms are generated using knowledge of the stimuli, attenuations, and measurements. Measurements may be coherently averaged in order to reduce the noise floor.

It is readily apparent to one skilled in the art that FIG. 6 and method 70 illustrate a general calibration configuration from which other specific embodiments can be derived. For example, calibration configuration 20 of FIG. 2 can be derived by setting attenuator 605 to 0. Method 30 of FIG. 3 can be derived by setting the variables described with reference to FIG. 7 such that A is 1, B is 2 and C is 1. Calibration configuration 40 of FIG. 4 can be derived by setting attenuator 604 to 0. Method 50 of FIG. 5 can be derived multiple ways, such as by setting A to 2, B to 1 and C to 2, or by setting A to 1, B to 2 and C to 2. One possible procedure for using calibration configuration 60 of FIG. 6 would be to set A to 1, B to 2 and C to 2.

FIG. 8 shows an embodiment of a calibration configuration according to the concepts described herein. Calibration configuration 80 illustrates a calibration configuration for use with multiple non-ideal sources 801 and 804, along with linear combiner 805. Non-ideal sources 801 and 804 are considered non-ideal because neither is expected to generate two different stimulus signals with highly linear performance when compared with the performance of DUT 803. Since neither non-ideal source 801 nor non-ideal source 804 is expected to produce two different stimulus signals linearly, they are each set to generate only a single stimulus each, s₁(t) and s₂(t). When signal s₁(t) is passed through combiner 805 alone, or else bypassed around combiner 805, DUT 803 responds with r₁(t). Receiver 802 measures r₁(t). When signal s₂(t) is passed through combiner 805 alone, or else bypassed around combiner 805, DUT 803 responds with r₂(t). Receiver 802 measures r₂(t). When signals s₁(t) and s₂(t) are linearly combined by combiner 805 to become input stimulus s₁(t) +s₂(t), DUT 803 responds with r₃(t). Receiver 802 measures r₃(t). It should be noted that measurements may be made using an attenuator, such that measured responses, after attenuation, are all approximately the same amplitude. That is, responses r₁(t), r₂(t) and r₃(t) may be attenuated such that receiver 802 measures signals that are all approximately the same amplitude.

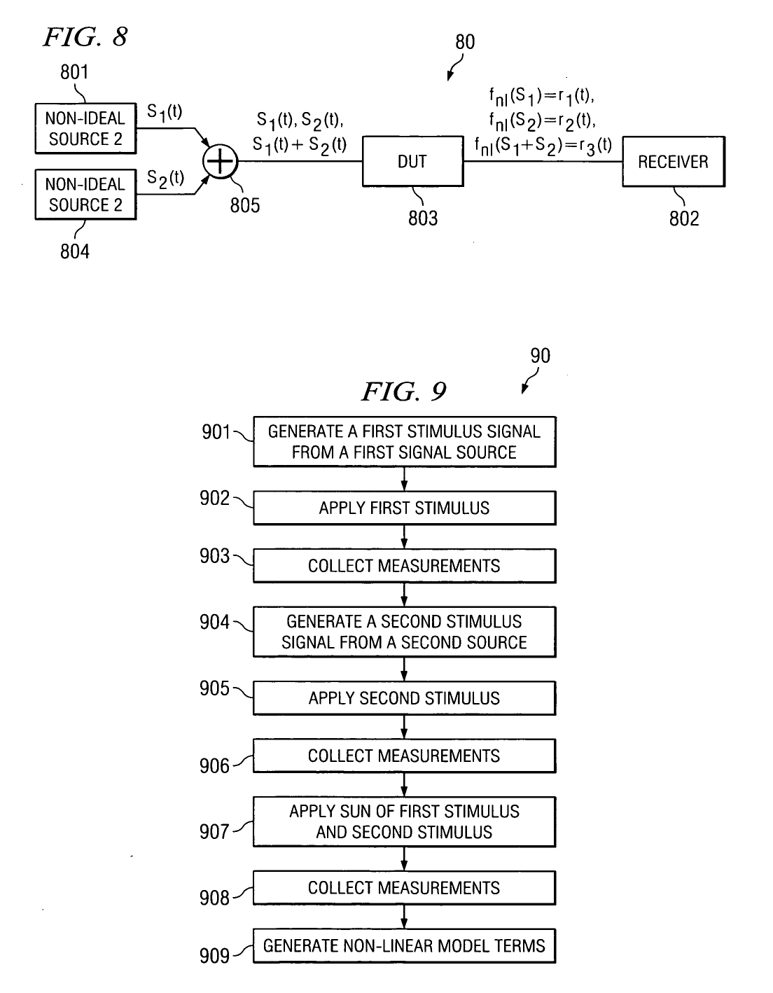

FIG. 9 shows method 90 illustrating an embodiment of a calibration method according to the concepts described herein. Reference is made to calibration configuration 80 of FIG. 8 to illustrate method 90. A first stimulus signal, s₁(t), is generated during process 901 and applied to DUT 803 during process 902. Receiver 802 collects a set of measurements 903. A second stimulus signal, s₂(t), is produced during process 904 and applied to DUT 803 during process 905. Receiver 802 collects a set of measurements 906. During process 907, s₁(t) and s₂(t) are linearly combined by linear combiner 805 and applied to DUT 803. Receiver 802 collects a set of measurements 908. Measurements may be coherently averaged in order to reduce the noise floor. Nonlinear model terms are generated during process 909. It should be noted that method 70 of FIG. 7 can parallel method 90 by setting A to 3, B to 1 and C to 1. It should also be noted that calibration configuration 80 of FIG. 8 could include an attenuator between DUT 803 and receiver 802. Method 90 may be derived from method 70 by setting A to 3 and using combiner 805 in at least one iteration of process 703.

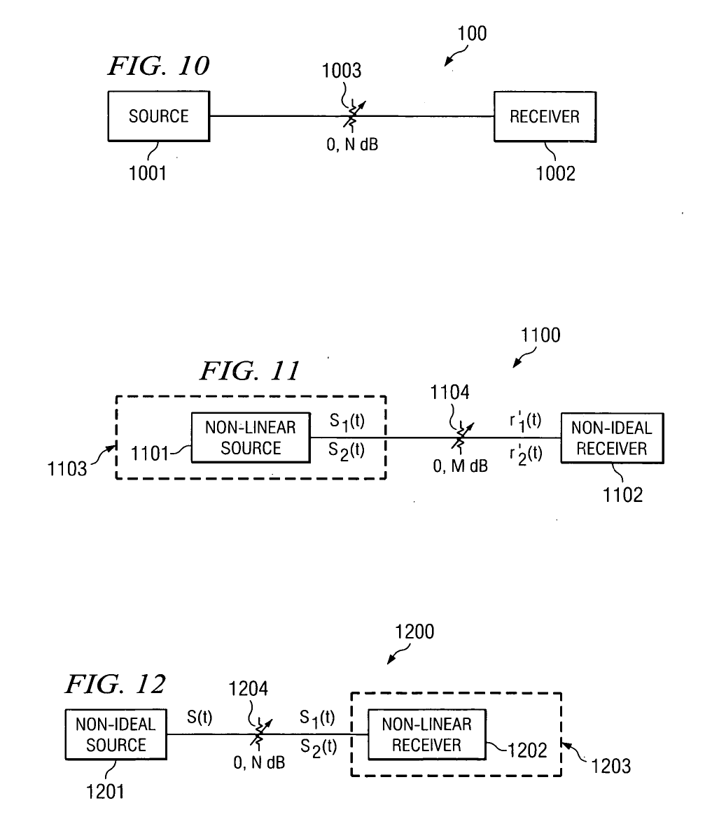

FIG. 10 shows an embodiment of a calibration configuration according to the concepts described herein. Calibration configuration 100 illustrates a calibration configuration for use with source 1001 and receiver 1002, where one is used as a reference and the other is to be calibrated. Attenuator 1003 prevents possible nonlinearities in the reference from affecting calibration of the other device.

40 It is also readily apparent to one skilled in the art that FIG. 6 and method 70 illustrate a general calibration configuration for which a DUT is considered to be either the signal source itself or else the signal receiver. For example, calibration configuration 100 of FIG. 10 may be derived multiple ways, such as by setting attenuator 604 to 0 and combining DUT 603 with non-ideal source 601, or else by setting attenuator 605 to 0 and combining DUT 603 with non-ideal receiver 602. One possible adaptation for using method 70 of FIG. 7 to calibrate a nonlinear source with a non-ideal receiver as a reference would be to set A to a value greater than 1, B to 1, and C to a value greater than 1. One possible adaptation for using method 70 of FIG. 7 to calibrate a nonlinear receiver with a non-ideal source as a reference would be to set A to 1, C to 1, and B to a value greater than 1. Additionally, calibration configuration 80 of FIG. 8 may be used to calibrate a nonlinear receiver by combining DUT 803 with receiver 802, and using method 90 of FIG. 9.

FIG. 11 shows an embodiment of a calibration configuration according to the concepts described herein. Calibration configuration 110 illustrates a calibration configuration for calibrating nonlinear source 1101, shown within nonlinear model 1103. Nonlinear source 1101 generates two waveforms, s₁(t) and s₂(t), which are intended to differ by a scale factor, but may include nonlinearities attributable to source 1101 that are to be modeled for calibration purposes. Attenuator 1104 prevents possible nonlinearities in non-ideal receiver 1102 from affecting calibration of nonlinear source 1101. Attenuator 1104 may be switched to an attenuation value of 0 dB, such that s₁(t) is sent to non-ideal receiver 1102. In this arrangement, r′₁(t) is equal to s₁(t). Attenuator 1104 may be set to an attenuation value of M dB to attenuate s₂(t) to r′₂(t), where M is chosen such that r′₂(t) has approximately the same amplitude as r′₁(t). In this way, non-ideal receiver 1102 may be assumed to be linear over the range of amplitudes from that of r′₁(t) through that of r′₂(t). Thus, any nonlinearities in the measured signals r′₁(t) and r′₂(t) are attributed to nonlinear source 1101, rather than non-ideal receiver 1102.

FIG. 12 shows an embodiment of a calibration configuration according to the concepts described herein. Calibration configuration 120 illustrates a calibration configuration for calibrating nonlinear receiver 1202, shown within nonlinear model 1203. Non-ideal source 1201 generates a single waveform, s(t), which is either left unattenuated as s₁(t), or attenuated by N dB to s₂(t). In calibration configuration 120, nonlinearities attributable to receiver 1202 are to be modeled for calibration purposes. Attenuator 1204 prevents possible nonlinearities in non-ideal source 1201 from affecting calibration of nonlinear receiver 1202. Attenuator 1204 may be switched to an attenuation value of 0 dB, such that s(t) is sent to nonlinear receiver 1102. In this arrangement, s₁(t) is equal to s(t). Attenuator 1104 may be set to an attenuation value of N dB to attenuate s(t) to s₂(t). In this way, nonlinearities in non-ideal source 1102 will not affect measurements. Thus, any nonlinearities in the measured signals s, (t) and s₂(t) are attributed to nonlinear receiver 1202, rather than non-ideal source 1201.

Since scaling and additive properties of linear systems are not obeyed in nonlinear systems, linearly scaling or adding signals outside a device to be calibrated highlights the difference between linear and nonlinear system behavior. Such differences may be used to build and calibrate nonlinear models of the behavior. While sources and receivers may not replicate or measure a known signal perfectly, their behavior for an arbitrary signal is often suitably repeatable. This repeatability can be used to coherently average signals, which recovers dynamic range that may be lost by attenuation. Once the nonlinear characteristics of a DUT, signal source or receiver have been determined using the configurations, methods, or concepts provided above, generation of a mathematical model is possible.

One method is to use the discrete Volterra series representation for a nonlinear system to describe nonlinear behavior. In the following representation, nonlinear terms are shown as the second and subsequent summations. Notice that nonlinear distortion terms are represented as higher order products of arbitrarily delayed versions of the stimulus. This representation and measured data demonstrate that as the stimulus decreases in amplitude, contributions from nonlinear terms diminish faster than linear terms.

$$\begin{matrix}r [ n ] = f ( s [ n ] ) \\ = {c}_{0} + {\sum }_{i} {c}_{i} s [ n + i ] + {\sum }_{i , j} {c}_{i , j} s [ n + i ] s [ n + j ] + \\ {\sum }_{i , j , k} {c}_{i , j , k} s [ n + i ] s [ n + j ] s [ n + k ] + …\end{matrix} \qquad ( 1 )$$

One may substitute the measured response as a reasonable estimate of the stimulus when modeling nonlinear behavior for an ultralinear system. In such a system, the higher order distortion coefficients (c_{i,j}, C_{i,j,k}, . . . ) are much smaller than the linear coefficients. As a result, the higher order products formed by the substitution will be much smaller than dominant nonlinear terms modeled.

A first calibration approach describes the responses, r₁(t) and r₂(t), to stimuli s₁(t) and s₂(t) in terms of their Volterra series representations.

$$\begin{matrix}{r}_{1} [ n ] = {a}_{0} + {\sum }_{i} {a}_{i} {s}_{1} [ n + i ] + {\sum }_{i , j} {a}_{i , j} {s}_{1} [ n + i ] {s}_{1} [ n + j ] + {\sum }_{i , j , k} {a}_{i , j , k} {s}_{1} [ n + i ] {s}_{1} [ n + j ] {s}_{1} [ n + k ] + … \\ and & ( 2 ) \\ {r}_{2} [ n ] = {a}_{0} + {\sum }_{i} {a}_{i} {s}_{2} [ n + i ] + {\sum }_{i , j} {a}_{i , j} {s}_{2} [ n + i ] {s}_{2} [ n + j ] + {\sum }_{i , j , k} {a}_{i , j , k} {s}_{2} [ n + i ] {s}_{2} [ n + j ] {s}_{2} [ n + k ] + … & ( 3 )\end{matrix}$$

where

$${s}_{2} [ n ] = α {\sum }_{i} {c}_{i} {s}_{1} [ n + i ]$$

models the both the attenuation and frequency dependence of the switched-in attenuator.

Since s₂ is attenuated, then r₂ (the system response of the attenuated stimulus) is more linear than r₁. If we treat r₂ as perfectly linear, then we may write the error as a function of the nonlinear behavior of r₁.

$${r}_{2} [ n ] \approx {a}_{0} + {\sum }_{i} {a}_{i} {s}_{2} [ n + i ] . \qquad ( 4 )$$

Substituting for s₂(t),

$$\begin{matrix}{r}_{2} [ n ] \approx {a}_{0} + α {\sum }_{i , j} {a}_{i} {c}_{j} {s}_{1} [ n + i + j ] \approx {a}_{0} + α {\sum }_{l} {b}_{l} {s}_{1} [ n + l ] & ( 5 ) \\ {r}_{2} [ n ] - α \cdot {r}_{1} [ n ] \approx {a}_{0} + α {\sum }_{l} {b}_{l} {s}_{1} [ n + l ] - α [ {a}_{0} + {\sum }_{i} {a}_{i} {s}_{1} [ n + i ] + {\sum }_{i , j} {a}_{i , j} {s}_{1} [ n + i ] {s}_{1} [ n + j ] + {\sum }_{i , j , k} {a}_{i , j , k} {s}_{1} [ n + i ] {s}_{1} [ n + j ] {s}_{1} [ n + k ] + … ] & ( 6 ) \\ {r}_{2} [ n ] - α \cdot {r}_{1} [ n ] \approx ( 1 - α ) {a}_{0} - α [ {\sum }_{l} {d}_{l} {s}_{1} [ n + l ] + {\sum }_{i , j} {a}_{i , j} {s}_{1} [ n + i ] {s}_{1} [ n + j ] + {\sum }_{i , j , k} {a}_{i , j , k} {s}_{1} [ n + i ] {s}_{1} [ n + j ] {s}_{1} [ n + k ] + … ] & ( 7 )\end{matrix}$$

A simple least squares fit to the nonlinear model may be used to determine the coefficients. For example, to fit a model of the form:

$${f}_{NL} ( s [ n ] ) = {\sum }_{i = - 1}^{1} {d}_{i} s [ n + i ] + {a}_{- 1 , 0} s [ n - 1 ] s [ n ] + {{a}_{0 , 0 , 0} ( s [ n ] )}^{3} \qquad ( 8 )$$

with an ideal attenuator factor α=0.5, and N sample length stimulus and response waveforms, we compose the following matrices:

$$y = [ \begin{matrix}{r}_{2} [ 2 ] - 0.5 \cdot {r}_{1} [ 2 ] \\ {r}_{2} [ 3 ] - 0.5 \cdot {r}_{1} [ 3 ] \\ … \\ {r}_{2} [ N - 1 ] - 0.5 \cdot {r}_{1} [ N - 1 ]\end{matrix} ] , \\ A = [ \begin{matrix}{s}_{1} [ 1 ] & {s}_{1} [ 2 ] & {s}_{1} [ 3 ] & {s}_{1} [ 1 ] {s}_{1} [ 2 ] & {( {s}_{1} [ 2 ] )}^{3} \\ {s}_{1} [ 2 ] & {s}_{1} [ 3 ] & {s}_{1} [ 4 ] & {s}_{1} [ 2 ] {s}_{1} [ 3 ] & {( {s}_{1} [ 3 ] )}^{3} \\ … & … & … & … & … \\ {s}_{1} [ N - 2 ] & {s}_{1} [ N - 1 ] & {s}_{1} [ N ] & {s}_{1} [ N - 2 ] {s}_{1} [ N - 1 ] & {( {s}_{1} [ N - 1 ] )}^{3}\end{matrix} ] \qquad ( 9 )$$

The formal solution to y=A·xᵢₛ is given by xᵢₛ=(A^{T}A)⁻A^{T}y, where

$${x}_{ls} = [ \begin{matrix}- α \cdot {d}_{- 1} \\ - α \cdot {d}_{0} \\ - α \cdot {d}_{1} \\ - α \cdot {a}_{- 1 , 0} \\ - α \cdot {a}_{0 , 0 , 0}\end{matrix} ] \qquad ( 10 )$$

There may be additional methods employed to correct for the linear differences between the first and second stimulus. Various techniques are available to estimate the time delay between r₁ and r₂. These techniques will not be discussed here. Actual time alignment is achieved by interpolation of the stimulus waveform by the detected delay value. A more complete equalization may take the form of a filter, with a separate interpolation to remove time offsets.

The concepts described herein describe an alternate approach to the Volterra series, using a linear least squares fit on a weakly nonlinear system. In this example, the response r₂ to attenuated stimulus s₂ remains weakly nonlinear. Assume we are attempting to model an ultra linear system that exhibits weak nonlinear behavior. We excite that system with some stimulus s, and measure a response r, that is a nonlinear function of s.

$$r [ n ] \approx {c}_{0} + {\sum }_{i} {c}_{i} s [ n + i ] + {\sum }_{i , j} {c}_{i , j} \hat{s} [ n + i ] \hat{s} [ n + j ] + {\sum }_{i , j , k} {c}_{i , j , k} \hat{s} [ n + i ] \hat{s} [ n + k ] + … \qquad ( 11 )$$

$$\hat{s} [ n ] ≅ - {c}_{0} + {\sum }_{i} {d}_{i} r [ n + i ] ,$$

where the linear coefficients di are chosen to invert the linear response.

Alternately, one may re-write the above expression to reverse the relationship between s[n] and r[n].

$$s [ n ] \approx \hat{s} [ n ] - {\sum }_{i , j} {c}_{i , j} \hat{s} [ n + i ] \hat{s} [ n + j ] - {\sum }_{i , j , k} {c}_{i , j , k} \hat{s} [ n + i ] \hat{s} [ n + j ] \hat{s} [ n + k ] - … \qquad ( 12 )$$

If we make a measurement (r₁) and assume that our system doesn't introduce much amplitude or phase distortion, (dᵢ→0 for i≠0 and dᵢ→1 for i =0 ) then we may simplify the above as:

$${s}_{1} [ n ] \approx {r}_{1} [ n ] - {\sum }_{i , j} {c}_{i , j} {r}_{1} [ n + i ] {r}_{1} [ n + j ] - {\sum }_{i , j , k} {c}_{i , j , k} {r}_{1} [ n + i ] {r}_{1} [ n + j ] {r}_{1} [ n + k ] … \qquad ( 13 )$$

We make a second measurement (r₂) of an attenuated stimulus (s₂), where

$${s}_{2} [ n ] = α ( 1 + ɛ ) {\sum }_{i} {c}_{i} {s}_{1} [ n + i ] \qquad ( 14 )$$

models both the attenuation and frequency dependence of the attenuator. Note that α is our estimate of the attenuation factor while ε represents the error in our estimate.

We assert that the time delay terms (cᵢ) and distortion terms (c_{i,j} . . . ) are small. We expect ε is small with respect to the stimulus. Notice that we may write an expression for the response of an attenuated stimulus by using exactly the same distortion function used in the first stimulus response pair. If we substitute for s₁ and recognize that the attenuator frequency response terms are likely small, and drop higher order terms, we find:

$${s}_{2} [ n ] \approx α ( 1 + ɛ ) {r}_{1} [ n ] + α ( 1 + ɛ ) {\sum }_{i \neq 0} {c}_{i} {r}_{1} [ n + i ] + - α ( 1 + ɛ ) {\sum }_{i , j} {c}_{i , j} {r}_{1} [ n + i ] {r}_{1} [ n + j ] - α ( 1 + ɛ ) {\sum }_{i , j , k} {c}_{i , j , k} {r}_{1} [ n + i ] {r}_{1} [ n + j ] {r}_{1} [ n + k ] - … \qquad ( 15 )$$

We alternately write the response to the second stimulus using (1).

$${r}_{2} [ n ] \approx {c}_{0} {\sum }_{i} {c}_{i} {s}_{2} [ n + i ] + {\sum }_{i , j} {c}_{i , j} {s}_{2} [ n + i ] {s}_{2} [ n + j ] + {\sum }_{i , j , k} {c}_{i , j , k} {s}_{2} [ n + i ] {s}_{2} [ n + j ] {s}_{2} [ n + k ] + … \qquad ( 16 )$$

Substituting the expression for s₂ into the above, asserting that both higher order terms and again the time delay terms (cᵢ), distortion terms (c_{i,j} . . . ) and estimation error (E) are small, yields:

$${r}_{2} [ n ] \approx α ( 1 + ɛ ) {r}_{1} [ n ] + α {\sum }_{i \neq 0} {c}_{i} {r}_{1} [ n + i ] + - α {\sum }_{i , j} {c}_{i , j} {r}_{1} [ n + i ] {r}_{1} [ n + j ] - α {\sum }_{i , j , k} {c}_{i , j , k} {r}_{1} [ n + i ] {r}_{1} [ n + j ] {r}_{1} [ n + k ] - … + {α}^{2} {\sum }_{i , j} {c}_{i , j} {r}_{1} [ n + i ] {r}_{1} [ n + j ] + {α}^{3} {\sum }_{i , j , k} {c}_{i , j , k} {r}_{1} [ n + i ] {s}_{1} [ n + j ] {r}_{1} [ n + k ] + … \qquad ( 17 )$$

Finally, to cast this in a form suitable for least squares, we subtract r₁ from both sides:

$${r}_{2} [ n ] - α {r}_{1} [ n ] \approx αɛ \cdot {r}_{1} [ n ] + α {\sum }_{i \neq 0} {c}_{i} {r}_{1} [ n + i ] ++ ( {α}^{2} - α ) {\sum }_{i , j} {c}_{i , j} {r}_{1} [ n + i ] {r}_{1} [ n + j ] + ( {α}^{3} - α ) {\sum }_{i , j , k} {c}_{i , j , k} {r}_{1} [ n + i ] {s}_{1} [ n + j ] {r}_{1} [ n + k ] - … \qquad ( 18 )$$

Given the known response vectors r₁ [n] and r₂[n], we may form above an over determined system of equations. Just as in the first example, this system is readily solvable using least squares techniques. Keep in mind that α is known and ε may be determined from the solution. One may then update the attenuation estimate a and find a new solution with a reduced estimation error ε. This procedure may be iterated until a suitable level of estimation error is attained.

The attenuated stimulus calibration (ASCal) technique may also be used for continuous adaptive nonlinear equalization. In this circumstance, the designer must have additional hardware resources available. Such a system must contain an identical (attenuated) signal path that is sufficiently similar in distortion behavior to merit this approach. The designer must also contend with the necessity for coherent signal averaging to lower the noise floor in the attenuated stimulus case. ASCal relies on trading off measurement time with dynamic range. This trade may be useful for infrequent calibration, but may be less practical for continuous measurement.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of calibrating a device, said method comprising:
generating at least one signal with at least one signal source applying said at least one signal to an input of said device;
measuring at least one response of said device with a receiver; and
changing an attenuation value of at least one attenuator disposed in a signal path between said at least one signal source and said receiver, wherein said changing an attenuation allows calculation of nonlinear distortion terms for a mathematical model using characteristics of said at least one attenuator and said at least one signal source.

2. The method of claim 1 wherein at least one of said at least one attenuator is disposed between said signal source and said device.

3. The method of claim 1 wherein at least one of said at least one attenuator is disposed between said signal source and said receiver.

4. The method of claim 1 wherein said at least one attenuator has an attenuation value setting of zero.

5. The method of claim 1 wherein said calculating comprises using a discrete Volterra series representation for a non-linear system.

6. The method of claim 1 wherein said calculating comprises using a least squares fit.

7. The method of claim 1 further comprising using coherent averaging for said measurements.

8. A method of model calibration for a device, said method comprising:
generating a stimulus;
attenuating said stimulus;
applying said attenuated stimulus to said device;
attenuating a response of said device to said attenuated stimulus;
measuring said attenuated response;
repeating generating through measuring at least once, wherein at least one of said attenuation of said stimulus and said attenuation of said response is changed; and
calculating nonlinear distortion terms of a mathematical model using two or more combinations of said stimulus, said attenuation of said stimulus, said attenuation of said response and said measurement.

9. The method of claim 8 wherein an attenuation applied during said attenuating a response is changed at least once.

10. The method of claim 9 wherein said change in said attenuation adjusts said measured attenuated response to approximately a same amplitude as a previous one of said measured attenuated responses.

11. The method of claim 8 wherein an attenuation applied during said attenuating said stimulus is changed at least once.

12. The method of claim 8 wherein said stimulus is changed at least once.

13. The method of claim 8 wherein one of said attenuation of said stimulus and said attenuation of said response has an attenuation value of zero.

14. The method of claim 8 wherein said calculating comprises using a discrete Volterra series representation for a non-linear system.

15. The method of claim 8 wherein said calculating comprises using a least squares fit.

16. The method of claim 8 further comprising using coherent averaging for said measurements.

17. A system for calibrating a device, said system comprising:
at least one signal source coupled to an input of said device;
a receiver coupled to an output of said device; and
at least one attenuator switchably disposed in a signal path between said signal source and said receiver, wherein measurements made with said receiver allow calculation of nonlinear distortion terms for a mathematical model using characteristics of said at least one attenuator and said at least one signal source.

18. The system of claim 17 wherein said first set of one or more attenuators is disposed between said signal source and said device.

19. The system of claim 17 wherein said first set of one or more attenuators is disposed between said device and said receiver.

20. The system of claim 17 further comprising a second set of one or more attenuators wherein said first set of one or more attenuators is disposed between said signal source and said device and said second set of one or more attenuators is disposed between said device and said receiver.

21. A method of model calibration for a device, said method comprising:
generating a first stimulus with a first signal source;
stimulating said device with said first stimulus;
measuring a first response of said device to said first stimulus;
generating a second stimulus with a second signal source;
stimulating said device with said second stimulus;
measuring a second response of said device to said second stimulus;
linearly combining said first stimulus with said second stimulus;
stimulating said device with said combination;
measuring a third response of said device to said combination; and
calculating nonlinear distortion terms of a mathematical model using said first stimulus, said measured first response, said second stimulus, said measured second response, said combination and said measured third response.

22. The method of claim 21 wherein said device is a receiver.

23. A system for calibrating a device, said system comprising:
two or more signal sources; and
a combiner disposed between said two or more signal sources, said combiner operable to selectively couple a combination of one or more of said signal sources to an input of said device.

24. The system of claim 23 further comprising a receiver coupled to an output of said device.

25. The system of claim 24 further comprising one or more attenuators switchably disposed in a signal path between said device and said receiver.

26. The system of claim 23 wherein said device is a receiver.

27. A method of calibrating a signal source, said method comprising:
generating a first signal with said signal source;
measuring said first signal;
generating a second signal with said signal source;
attenuating said second signal such that said attenuated second signal is approximately the same amplitude as said first signal;
measuring said attenuated second signal; and
calculating nonlinear distortion terms for a mathematical model using characteristics of said first signal and said second signal along with a value of said attenuation.

28. A method of calibrating a receiver, said method comprising:
generating a signal with a signal source;
measuring said signal with said receiver;
attenuating said signal;
measuring said attenuated signal;
calculating nonlinear distortion terms for a mathematical model using characteristics of said measurements of said signal and said measurements of said attenuated signal along with a value of said attenuation.
